(19) United States
(12) Patent Application Publication
(10) Pub. No.: US 2007/0235747 A1
(43) Pub. Date: Oct. 11, 2007

(54) Light source with compliant interface

(76) Inventors: Sundar A/L Natarajan Yoganandan, Penang (MY); Siew It Pang, Penang (MY); Thye Linn Mok, Penang (MY)

Correspondence Address: Kathy Manke;Avago Technologies Limited, 4380 Ziegler Road, Fort Collins, CO, 80525, US

(21) Appl. No.: 11/412,697

(22) Filed: Apr. 27, 2006

Related U.S. Application Data
(63) Continuation-in-part of application No. 11/400,951, filed on Apr. 10, 2006, now abandoned.

(51) Int. Cl. H01L 33/00

(52) U.S. Cl. 257/99

(57) ABSTRACT

A compliant interface is added above the top housing of a light source, such as an LED during LED manufacture. The compliant interface allows for a low light loss transfer between the surface of the light guide material. The compliant structure is, in one embodiment, a light transparent compliant silicone molded (by curing the liquid silicone) onto the top surface of the light source. In one embodiment, the compliant interface can be integrated as part of the encapsulated material surrounding the LED chip.

### CROSS-REFERENCE TO RELATED APPLICATIONS

This application claims priority benefit of U.S. patent application Ser. No. 11/400,951 entitled “LIGHT SOURCE WITH COMPLIANT INTERFACE,” filed Apr. 10, 2006, the disclosure of which is hereby incorporated herein by reference.

### TECHNICAL FIELD

This invention relates to light sources and more particularly to light sources having compliant interfaces and even more particularly to such light sources for use in forming light guide panels.

### BACKGROUND OF THE INVENTION

Light sources are used for many applications. For example, an LED light source having a flat top is pressed into contact with light guide material to form light guide panels (LGP). In such applications, the light from the LED source must pass in and through the LGP and thus it is important that the bond between the LED and the light guide material have low light loss. As LEDs are currently constructed, the interface between the LED and the panel results in air gaps being formed. These are gaps have relatively high light loss.

A typical solution to reduce the light loss (and thereby increase the efficiency of the device's performance) is to flow a compliant sealer (such as silicone) between the top of the LED and the light guide material. This gap-filling solution is time-consuming and requires skill to achieve a proper insertion of the compliant sealant. Excess sealant seeps out and causes additional problems. Accordingly, the yield rate using this procedure is poor.

### SUMMARY OF THE INVENTION

A compliant interface is added above the top housing of a light source, such as an LED during LED manufacture. The compliant interface allows for a low light loss transfer between the surface of the light guide material. The compliant structure is, in one embodiment, a light transparent compliant silicone molded (by curing the liquid silicone) onto the top surface of the light source. In one embodiment, the compliant interface can be integrated as part of the encapsulated material surrounding the LED chip.

### BRIEF DESCRIPTION OF THE DRAWINGS

FIG. 1 shows one embodiment of a light device with a compliant interface;

FIG. 2 shows one embodiment of a light source mated with a light guide material to form a LGP; and

FIGS. 3 and 4 show embodiments for constructing the compliant interface.

### DETAILED DESCRIPTION OF THE INVENTION

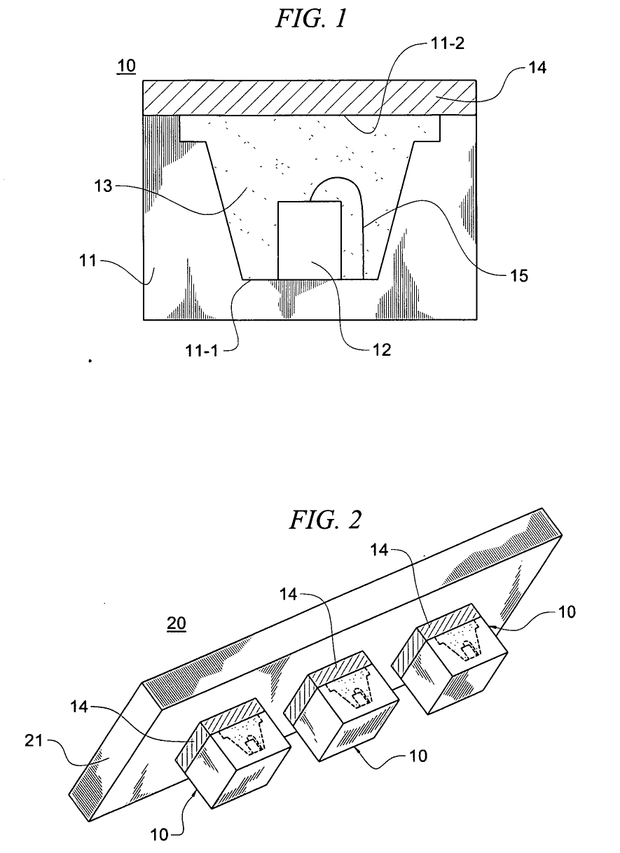

FIG. 1 shows one embodiment 10 of a light device having a compliant interface. As shown, device 10 consists of housing 11 having a cavity constructed therein with the cavity being closed at its bottom area 11-1 and open at top area 11-2. Positioned within the cavity of housing 11 is a light source, such as LED chip 12. Chip 12 is connected in the well-known manner such that electrical energy is connected from an external source through the bottom of LED chip 12 and also connected by wire bond 15.

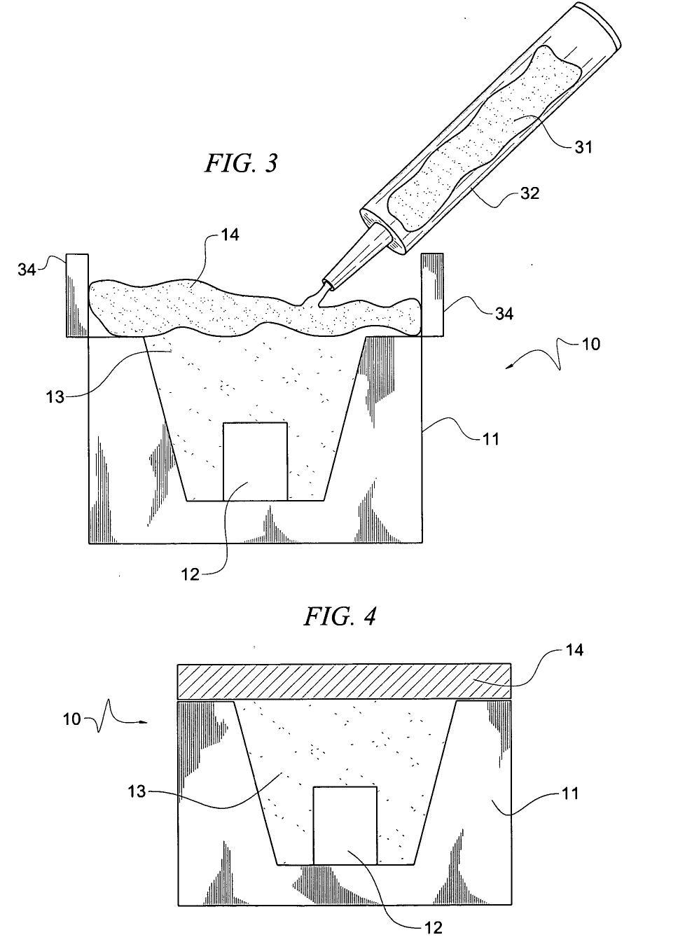

During construction of the light device encapsulant 13, which can, for example, be liquid silicone, is flowed around light source 12. This encapsulant fills the cavity from bottom surface 11-1 to top surface 11-2. The top surface of the cavity is the same height as housing 11 since housing 11 is the mold by which encapsulant 13 is formed. Encapsulant 13 is cured to form a flat-topped LED in the well-known manner. At this point, compliant layer 14 is formed above housing 11, as will be discussed with respect to FIGS. 3 and 4. This compliant layer 14 can be constructed, for example, from low light loss silicone, such as, for example, silicone Product Number IVS4542, JCR6140, or EG6301.

FIG. 2 shows one embodiment of light source 10 mated with light guide material 21 such that light emitting from device 10 shines through the light guide material forming a light guide panel (LGP). In typical operation, many such light devices would be positioned on the relative flat surface of material 21 to form LGP 20. Note that while the bottom surface of material 21 is relatively flat, so as to make contact with compliant material 14 of device 10, the upper surface can have any geometric shape desired depending upon the application to which the panel will be utilized. The fact that layer 14 transmits light with low loss and the material is compliant, allows it to conform to the surface irregularities of material 21. This allows more light to be transferred to the LGP from device 10 than would have been communicated using prior art devices in which liquid silicone is injected after mating. In one embodiment, the thickness of layer 14 would be 0.1 mm to 2.0 mm.

FIG. 3 shows one embodiment of the construction of layer 14 such that a barrier or framework is established around and above housing 11 of device 10. Inside this boundary liquid material, such as silicone 31 from applicator 32, is allowed to flow thereby forming layer 14 positioned above housing 11, but in contact therewith. Encapsulant 13 in conjunction with the top of housing 11 forms the foundation upon which layer 14 is positioned. In one embodiment material 14 bonds with the top surface of encapsulate 13 and housing 11 to form a continuous integral unit. This bonding can occur, for example, as material 31 cures. Curing can occur, for example, using heat or ultraviolet light. After curing, barriers 34 can be removed as shown in FIG. 4.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A light device comprising:
a light source;
a light transmitting medium surrounding said light source for facilitating light transfer from said light source to a top surface of said light device; and
a compliant light conducting pad constructed on said top surface area.

2. The device of claim 1 wherein said compliant pad is a material different from said light transmitting medium.

3. The device of claim 2 wherein said light transmitting medium is encapsulant material and said pad is cured silicone.

4. The device of claim 1 further comprising:
mating a surface of light guide material against said compliant pad.

5. The method of manufacturing a light device, said method comprising:
placing an LED chip within a cavity in a housing of said light device;
filling said cavity with encapsulant material, said encapsulant material surrounding a placed LED;
forming a flat surface above said encapsulant, said flat surface being compliant and light conductive.

6. The method of claim 5 wherein said flat surface is a material different from said encapsulant material within.

7. The method of claim 5 wherein said filling is accomplished using uncured encapsulant material and allowing said encapsulant materials to cure to form a top surface even with a top surface of said housing and wherein said forming is accomplished using uncured silicone placed over said cured encapsulant.

8. A light panel comprising:
a panel of light guide material, said light guide material having at least one relatively flat side; and
at least one light source mated with said flat side of said light guide material, said light source having light conducting compliant structure adapted to be interposed between said light source and light guide material.

9. The method of claim 8 wherein said light source is contained in a relatively rigid housing.

10. The method of claim 9 wherein said compliant structure is a layer of material constructed above said light source housing.

11. The method of claim 10 wherein said light source comprises:
a LED chip embedded within said housing, said LED chip surrounded by encapsulant material, said encapsulant material forming a flat surface with a top surface of said housing, said flat surface forming a foundation for said compliant structure.

12. The method of claim 11 wherein said compliant structure is cured silicone.

13. The method of claim 12 wherein said silicone is cured prior to said light source being mated to said light guide material.

14. A light emitting device comprising;
a housing forming a cavity, said cavity having a closed bottom area and an open top area, said top area opposing said bottom area;
a light source positioned within said cavity closer to said bottom area of said cavity than to said top area;
encapsulant material surrounding said light source and filling said cavity to a point even with said top area; and
a light conductive compliant layer of material abutting said encapsulant, said light conductive material extending above said top of said cavity and attached to at least a portion of said encapsulant.

15. The device of claim 14 wherein said light conductive compliant layer is formed by flowing said compliant material onto said encapsulant and allowing said layer to cure and bond in contact with said encapsulant material.

16. The device of claim 15 wherein said layer is approximately 0.1 mm to 2.0 mm thick.

17. The device of claim 16 wherein said encapsulant is formed by flowing encapsulant material around said light source within said cavity and allowing said encapsulant to cure.

18. The device of claim 17 wherein said light source is at least one LED chip.

19. The device of claim 15 further comprising:
light conducting material having at least one relative flat surface, said flat surface in mating relationship with an outer surface of said compliant layer, said outer surface being the surface away from said encapsulant material.

20. The device of claim 19 wherein said light source is at least one LED chip.
